(19) United States
(12) Patent Application Publication
(10) Pub. No.: US 2026/0120999 A1
(43) Pub. Date: Apr. 30, 2026

(54) TRANSFORMATION SYSTEM FOR CONNECTING A PLASMA PROCESS CONTROL SYSTEM TO AN IMPEDANCE MATCHING CIRCUIT, PLASMA-GENERATING SYSTEM HAVING SUCH A TRANSFORMATION SYSTEM, AND METHOD FOR GENERATING A TRANSFORMATION TABLE AND/OR A TRANSFORMATION FUNCTION

(71) Applicant: TRUMPF HÜTTINGER GMBH + CO. KG, Freiburg (DE)

(72) Inventor: Florian MAIER, Pfaffenweiler (DE)

(21) Appl. No.: 19/430,499

(22) Filed: Dec. 23, 2025

Related U.S. Application Data
(63) Continuation of application No. PCT/EP2024/068416, filed on Jun. 30, 2024.

(30) Foreign Application Priority Data
Jun. 30, 2023 (DE) 10 2023 117 398.7

(51) Int. Cl. H01J 37/32

(52) U.S. Cl. CPC H01J 37/32183

(57) ABSTRACT

A transformation system for connecting a plasma process control system to an impedance matching circuit A, the impedance matching circuit A being connectable to an RF generator and a plasma chamber and including a first transformation device and a communication device. The communication device is connectable to the plasma process control system and is designed to receive from the control system control data B for an impedance matching circuit B. The first transformation device is designed to transform the control data B for the impedance matching circuit B into control data A for the impedance matching circuit A. The transformation system is designed to provide the control data A for controlling the impedance matching circuit A. Alternatively or in addition, the transformation system is designed to receive information data A from the impedance matching circuit A.

### CROSS REFERENCE TO RELATED APPLICATIONS

This application is a continuation of International Application No. PCT/EP2024/068416 (WO 2025/003506 A1), filed on Jun. 30, 2024, and claims benefit to German Patent Application No. DE 10 2023 117 398.7, filed on Jun. 30, 2023. The aforementioned applications are hereby incorporated by reference herein.

### FIELD

The invention relates to a transformation system for connecting a plasma process control system to an impedance matching circuit, a plasma-generating system having such a transformation system and a method for generating a transformation table and/or a transformation function.

### BACKGROUND

The surface treatment of workpieces using plasma and gas lasers are industrial processes in which, in particular in a plasma chamber, a plasma is generated either using direct current or a radio-frequency alternating signal having an operating frequency in the range of several tens of kHz up to the GHz range.

The plasma chamber is connected to a radio-frequency generator (RF generator) via additional electronic components such as coils, capacitors, cables or transformers. These additional components can be oscillating circuits, filters, or impedance matching circuits.

Plasma processes represent a highly variable load for a radio-frequency generator, the load being dependent on the conditions in the plasma chamber. In particular, the properties of the workpiece, electrodes, and gas conditions are taken into account.

Radio-frequency generators have a limited operating range with respect to the impedance of the connected electrical load. If the load impedance leaves a permissible range, the required energy/power cannot be delivered to the consumer. Damage to the RF generator is also possible.

For this reason, an impedance matching circuit, also known as a “matchbox”, is commonly employed to transform the load impedance to the nominal impedance of the generator output.

Different types of impedance matching circuits are known. For example, the impedance matching circuits can be fixed and have a predetermined transformation effect, i.e., they consist of electrical components, for example, in particular coils and capacitors, which are not changed during operation. This is particularly useful for operations that are always consistent, such as with a gas laser. Furthermore, impedance matching circuits are known in which at least one of the components of the impedance matching circuits is mechanically variable. For example, motor-driven rotary capacitors are known, the capacitance value of which can be changed by changing the arrangement of the capacitor plates relative to one another. Furthermore, impedance matching circuits are known in which at least some of the components of the impedance matching circuit can be changed electrically or magnetically. For example, reactances can be switched on using semiconductor components, or reactances can be modified in their properties by applying electric and/or magnetic fields.

A plasma can, in a general sense, be assigned to three impedance ranges. There are very high impedances before ignition. In normal operation, i.e., during operation as intended with plasma, lower impedances are present. Very small impedances can occur in the case of unwanted local discharges, also called “arcs”, or plasma fluctuations. In addition to these three identified impedance ranges, other special conditions with other associated impedance values can occur. If the load impedance changes suddenly and the load impedance or the transformed load impedance moves out of a permissible impedance range, the RF generator or transmission devices between the RF generator and the plasma chamber can be damaged. There are also stable states of the plasma that are not desired.

An impedance matching circuit is described for example in the document DE 10 2009 001 355 A1. Plasma processes carried out using such a plasma-generating system, which includes at least the RF generator and the impedance matching circuit, must always be performed in exactly the same way to achieve the same result. This is all the more true since the plasma process is integrated into a semiconductor process. Semiconductor processes involve many more steps, each of which must take place within a precisely predefined framework. Every process parameter must always be exactly the same; otherwise, for example, a wafer cannot be produced reproducibly.

A problem arises when replacing one component of the plasma-generating system to another component. Reasons for such a replacement may lie in improved properties of the new component, for example, a lower energy consumption. For example, the impedance matching circuit B can be replaced by a new impedance matching circuit A, which is, for example, more efficient, can be operated over a wider frequency range, or can be adjusted more accurately or faster.

### SUMMARY

In an embodiment, the present disclosure provides a transformation system for connecting a plasma process control system to an impedance matching circuit A, wherein the impedance matching circuit A is connectable to an RF generator and a plasma chamber, the transformation system comprising a first transformation device and a communication device, wherein the communication device is connectable to the plasma process control system. The communication device is designed to receive from the plasma process control system control data B for an impedance matching circuit B. The first transformation device is designed to transform the control data B for the impedance matching circuit B into control data A for the impedance matching circuit A. The transformation system is designed to provide the control data A for controlling the impedance matching circuit A. Alternatively or in addition, the transformation system is designed to receive information data A from the impedance matching circuit A. The first transformation device is designed to transform the received information data A from the impedance matching circuit A into information data B of the impedance matching circuit B. The communication device is designed to transmit the information data B to the plasma process control system.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates an exemplary embodiment of a plasma-generating system comprising a plasma process control system, an impedance matching circuit B, wherein the impedance matching circuit B is connected to an RF generator and a plasma chamber;

FIG. 2, and FIG. 3 illustrate the plasma-generating system from FIG. 1, wherein the impedance matching circuit B is replaced by an impedance matching circuit A and wherein the plasma-generating system comprises the transformation system according to the present disclosure;

FIG. 4A, and FIG. 4B illustrate embodiments of how an impedance matching circuit can be constructed;

FIG. 5 illustrates an exemplary embodiment which explains how a transformation table and/or a transformation function for the transformation system can be generated;

FIG. 6A, and FIG. 6B illustrate differently adjustable impedances at the output terminal of the impedance matching circuit B and the impedance matching circuit A;

FIG. 7, and FIG. 8 illustrate exemplary embodiments of how a measuring unit can be designed to measure a current and a voltage; and

FIG. 9 illustrates a flowchart for a method which explains the operation of the transformation system.

### DETAILED DESCRIPTION

In an embodiment, the present disclosure provides a way to continue to achieve a stable and reproducible plasma process even when one component of the plasma-generating system is replaced by another component.

The foregoing is achieved by a transformation system for connecting a plasma process control system to an impedance matching circuit according to an embodiment of the present disclosure.

The transformation system according to the present disclosure is used for connecting a plasma process control system to an impedance matching circuit A. The impedance matching circuit A is connectable between an RF generator and a plasma chamber. The impedance matching circuit A is the impedance matching circuit that is to be controlled during operation. It can therefore also be called the “in-operation impedance matching circuit”. The transformation system comprises a first transformation device and a communication device, wherein the communication device is connectable to the plasma process control system. The communication device is designed to receive, in particular to receive from the plasma process control system, control data B for an impedance matching circuit B. The communication device can therefore also be called a data communication device. The impedance matching circuit B is the impedance matching circuit that is no longer in operation, i.e., it is to be replaced by the impedance matching circuit A, or has already been replaced. The impedance matching circuit B can therefore also be called the ‘non-operational impedance matching circuit’ and the control data B the ‘non-operational control data’. However, the plasma process was successfully operated at an earlier time by the impedance matching circuit B. A first transformation device is designed to transform the control data B for the impedance matching circuit B into control data A for the impedance matching circuit A. The first transformation device can therefore also be called the first data transformation device, and the control data A can also be called ‘in-operation control data’.

The transformation system is further designed to provide the control data A for controlling the impedance matching circuit A. Additionally or alternatively to the transformation of control data B into control data A, the transformation system, in particular the first transformation device, is designed to receive information data A from the impedance matching circuit A. The first transformation device is then designed to transform the received information data A from the impedance matching circuit A into information data B of the impedance matching circuit B. Information data A can also be called ‘in-operation information data’ and information data B can also be called ‘non-operational information data’. The communication device is designed to provide the information data B, in particular to transmit it to the plasma process control system. It is particularly advantageous that the transformation also takes place in this reverse direction, i.e., that information data A, which originates from the impedance matching circuit A, is transformed into information data B that appears as though it originated from the impedance matching circuit B. This ensures the proper operation of the plasma process control system, which, for example, displays this transformed information data B to a user or processes it further and uses it for control purposes if necessary.

Impedance matching circuit A and impedance matching circuit B have different properties. The different properties can be, for example: Efficiency, power loss, frequency dependence, component sizes used, switching components used, motors and/or other components. At the same time, the impedance matching circuit A is designed in such a way that it is suitable as a replacement for the impedance matching circuit B. This can mean that it is designed for comparable or greater power, comparable or wider frequency range, and comparable or wider input and output impedance range. It can do at least everything that was needed from the impedance matching circuit B in the plasma process, and more.

It is particularly advantageous that a transformation system is used which can be arranged between the impedance matching circuit A and, for example, a higher-level plasma process control system. This allows control commands, such as control data generated by the plasma process control system, to be transformed or modified and only forwarded to the impedance matching circuit A after such a transformation. The entire plasma process can thus be designed for the use with impedance matching circuit B. If the impedance matching circuit B is replaced by a newer impedance matching circuit A, control data B, which is used for controlling the impedance matching circuit B, cannot simply be used for controlling the impedance matching circuit A. If this control data B were simply used without transformation, the plasma process would suddenly produce different results.

As mentioned at the outset, one or both of the impedance matching circuits A/B can include at least one mechanically, in particular motor-driven, adjustable reactance, in particular in the form of at least one mechanically, in particular motor-driven, adjustable capacitance, in order to change the transformation ratio during operation of the impedance matching circuit. This allows different impedances to be provided at the output terminal of the impedance matching circuit, in order to transfer as much power as possible into the plasma via the plasma chamber. Furthermore, a defined impedance can also be achieved at the input terminal of the impedance matching circuit in order to reduce or prevent reflections back to the RF generator. The respective control data preferably comprises or consists of data from which the position of the at least one mechanically, in particular motor-driven, adjustable reactance can be determined directly or indirectly. The position of the at least one mechanically, in particular motor-driven, adjustable reactance can be different for two different impedance matching circuits in order to still achieve the same impedance at the output terminal or at the input terminal of the impedance matching circuit.

The transformation system according to the present disclosure not only allows the use of a new impedance matching circuit A, but the transformation system also eliminates the need for any modification of the plasma process supply system. This avoids the need to implement corresponding changes in the complex plasma process supply system, which can include controls for hundreds of method steps.

In an advantageous further development, the transformation system can be directly integrated into a data connection between the plasma process supply system and the impedance matching circuit A. The transformation system preferably acts as a so-called black box for the operator of the plasma process control system.

In an advantageous further development, the transformation system is designed to transmit the control data A to the impedance matching circuit A and to thereby control the impedance matching circuit A. The impedance matching circuit A is then designed to make adjustments according to the control data A or to execute the control data A.

In an advantageous further development, the first transformation device comprises a transformation table and/or a transformation function to transform the control data B for the impedance matching circuit B into control data A for the impedance matching circuit A. A corresponding transformation table can, for example, include a direct translation between position information for impedance matching circuit B and position information for impedance matching circuit A. If, for example, the impedance matching circuits A and B each comprise exactly one mechanically, in particular motor-driven, adjustable reactance, the transformation table can receive the information that a position of, for example, 5 mm or 20° for the impedance matching circuit B corresponds to a position of, for example, 12 mm or 53° for the impedance matching circuit A. If control data from the plasma process control system is now transmitted to the transformation device, which includes the corresponding position of, for example, 5 mm or 20° for the impedance matching circuit B, the translation device is designed to replace this position with the new position of, for example, 12 mm or 53° and transmit it to the impedance matching circuit A. The new position causes impedance matching circuit A to set the same impedance as the old position for impedance matching circuit B. Therefore, despite the new impedance matching circuit A, the plasma process is carried out with the same physical parameters.

The transformation table is therefore preferably a look-up table. In the event that the impedance matching circuit A comprises a plurality of adjustable reactances, particularly in the form of capacitances, there are correspondingly a plurality of new positions. Of course, the impedance matching circuit B can also include a plurality of adjustable reactances, especially in the form of capacitances, in which case there are correspondingly a plurality of positions. Preferably, for a position for a first adjustable reactance, there is a multitude of positions for a second adjustable reactance. This is the case for both the impedance matching circuit B and the impedance matching circuit A. For each pair of positions for the first adjustable reactance and the second adjustable reactance of impedance matching circuit B, there is a corresponding pair of positions for the first adjustable reactance and the second adjustable reactance of impedance matching circuit A.

Using a suitable transformation function can reduce the memory requirement. The transformation system is designed to insert the received control data B for the impedance matching circuit B into the transformation function and to obtain transformed control data A for the impedance matching circuit A based on the result of the transformation function.

In an advantageous embodiment, the control data B for the impedance matching circuit B comprises control variables for at least one mechanically, in particular motor-driven, adjustable reactance in the impedance matching circuit B. Furthermore, the control data A for the impedance matching circuit A comprises control variables for at least one mechanically, in particular motor-driven, adjustable reactance for the impedance matching circuit A.

In an advantageous further development, the control data for the impedance matching circuit B comprises position information and/or capacitance information for at least one mechanically, in particular motor-driven, adjustable reactance arranged in the impedance matching circuit B to provide a specific target impedance value at the output terminal of the impedance matching circuit B. The first transformation device is designed to transform the control data for the impedance matching circuit B into control data for the impedance matching circuit A, wherein the control data for the impedance matching circuit A comprises position information for at least one mechanically, in particular motor-driven, adjustable reactance arranged in the impedance matching circuit A. Using these transformed position data, the same target impedance value can be established at the output terminal of impedance matching circuit A as at the output terminal of impedance matching circuit B.

In an advantageous further development, the information data A comprises current position information for at least one mechanically, in particular motor-driven, reactance in the impedance matching circuit A and/or current capacitance information for at least one mechanically, in particular motor-driven, reactance in the impedance matching circuit A and/or a currently set transformation ratio in the impedance matching circuit A and/or a current efficiency of the impedance matching circuit A and/or at least a current value for a voltage and/or current at or in the impedance matching circuit A.

In an advantageous further development, the first transformation device comprises a transformation table and/or a transformation function to transform the information data A for the impedance matching circuit A into information data B for the impedance matching circuit B. This transformation table and/or transformation function can be structured similarly, but preferably inversely, to the transformation table and/or transformation function used to transform the control data.

In an advantageous further development, the communication device is designed to receive a target generator power B for the RF generator for use of the impedance matching circuit B from the plasma process control system. A second transformation device is designed to transform the target generator power B for use by the impedance matching circuit B into a target generator power A for use by the impedance matching circuit A. The second transformation device is further designed to transmit the transformed or modified target generator power A to the RF generator. This ensures that the radio frequency generator outputs the RF signal at a modified power level, so that the same power is delivered to the plasma. The power output should be modified if the impedance matching circuit A has an efficiency that differs from the efficiency of the impedance matching circuit B. The efficiency should preferably be related to the correspondingly set impedance at the output terminal of the impedance matching circuit. If the efficiency of impedance matching circuit A at a position of the at least one mechanically, in particular motor-driven, adjustable reactance, set via the transformed control variable, differs from that of impedance matching circuit B, the target generator power can be transformed to ensure that the same power is delivered to the plasma using impedance matching circuit A as with the older impedance matching circuit B. The plasma process control system does not require any modification.

In an advantageous further development, the second transformation device is designed to transform the target generator power B received from the plasma process control system as a function of a quantity, wherein the quantity can describe an efficiency difference between the impedance matching circuit A and the impedance matching circuit B.

In an advantageous further development, the second transformation device is designed to transform the target generator power B received from the plasma process control system as a function of an efficiency difference between an efficiency of the impedance matching circuit A and an efficiency of the impedance matching circuit B, wherein the efficiency of the impedance matching circuit A is obtained when operating with the transformed control variable A and wherein the efficiency of the impedance matching circuit B is obtained when operating with the manipulated variable B. If impedance matching circuit A is, for example, 20% more efficient than impedance matching circuit B, the RF generator's target generator power is to be reduced accordingly to ensure that the same power is supplied to the plasma.

In a further advantageous embodiment, the second transformation device is designed to reduce the target generator power received by the plasma process control system when the efficiency of the impedance matching circuit A is greater than the efficiency of the impedance matching circuit B. Additionally or alternatively, the second transformation device is designed to increase the target generator power received by the plasma process control system when the efficiency of the impedance matching circuit A is less than the efficiency of the impedance matching circuit B.

In an advantageous further development, the second transformation device is designed to receive an actual generator power from the RF generator with connected impedance matching circuit A. In a first alternative, the second transformation device is designed to increase the actual generator power when the efficiency of impedance matching circuit A is greater than the efficiency of impedance matching circuit B. The communication device is then designed to transmit the increased actual generator power to the plasma process control system. Additionally or alternatively, in a second alternative, the second transformation device is designed to reduce the actual generator power when the efficiency of impedance matching circuit A is less than the efficiency of impedance matching circuit B. The communication device is then designed to transmit the reduced actual generator power to the plasma process control system.

In an advantageous further development, the communication device is designed to receive a frequency setpoint for the RF generator from the plasma process control system. The second transformation device is designed to transmit the frequency setpoint to the RF generator without changing the frequency. Additionally or alternatively to transmitting a frequency setpoint for the RF generator, a start/stop signal or an information signal indicating whether the RF generator should generate a CW signal or a pulse signal to the RF generator without transformation can be transmitted.

The plasma-generating system according to the present disclosure comprises a transformation system as already described. The plasma-generating system also comprises an RF generator, an impedance matching circuit A and a, in particular higher-level, plasma process control system. Optionally, a consumer, in particular in the form of a plasma chamber, is also provided. The plasma process control system is connected to the transformation system, preferably via a cable connection. This cable connection is, for example, an optical and/or galvanic connection. The RF generator is connected to the impedance matching circuit A.

In an advantageous further development, the impedance matching circuit A is the currently used impedance matching circuit in the plasma-generating system, and the impedance matching circuit B is the impedance matching circuit that was previously used in the plasma-generating system, i.e., in the past. Corresponding plasma processes that can be provided by the plasma chamber were tested with the older impedance matching circuit B and should now also be used with the newer impedance matching circuit A.

In an advantageous further development of the plasma-generating system, the transformation system is designed as a separate system between the RF generator, the impedance matching circuit A and the plasma process control system. Alternatively, the transformation system is designed as a module in the RF generator and/or as a module in the impedance matching circuit A. Alternatively, the transformation system is designed as a module in the plasma process control system. A module can be a hardware module and/or a software module.

The method according to the present disclosure is used for generating a transformation table and/or a transformation function to transform control data for the impedance matching circuit B into control data for the impedance matching circuit A. In a first method step, a vector network analyzer (VNA) is connected to the input terminal and output terminal of the impedance matching circuit B. In a second method step, an impedance at the output terminal is determined for a position for at least one mechanically, in particular motor-driven, adjustable reactance of the impedance matching circuit B. In a third method step, the position of the at least one mechanically, in particular motor-driven, adjustable reactance of the impedance matching circuit B is changed and then the second method step is repeated. In a fourth method step, a vector network analyzer is connected to the input terminal and output terminal of the impedance matching circuit A. In a fifth method step, an impedance at the output terminal is determined for a position for at least one mechanically, in particular motor-driven, adjustable reactance of the impedance matching circuit A. In a sixth method step, the position of at least one mechanically, in particular motor-operated, adjustable reactance of the impedance matching circuit A is changed, and then the fifth method step is repeated. It is clear that method steps 1 to 3 and 4 to 6 can also be performed in reverse order. In this case, method steps 4 to 6 would be carried out before method steps 1 to 3. If the vector network analyzer has four ports, the impedance matching circuit A and the impedance matching circuit B can be measured simultaneously. In a seventh method step, a transformation table and/or a transformation function is created by which a position of the at least one mechanically, in particular motor-driven, adjustable reactance of the impedance matching circuit B can be transformed into a position for the at least one mechanically, in particular motor-driven, adjustable reactance of the impedance matching circuit A, wherein the impedance at the output terminal of the impedance matching circuit A is equal to the impedance at the output terminal of the impedance matching circuit B or deviates by less than a threshold value.

A further method according to the present disclosure describes the operation of the transformation system described at the beginning. The plasma process control system is connected to the impedance matching circuit A via the transformation system. In a first method step, a communication device of the transformation system receives control data B for an impedance matching circuit B from the plasma process control system. In a second method step, the first transformation device transforms the control data B for the impedance matching circuit B into control data A for the impedance matching circuit A. In a third method step, the transformation system provides the transformed control data A of the impedance matching circuit A. Additionally or alternatively to method steps 1 to 3, the following method steps can also be carried out. In a fourth method step, the transformation system receives information data A from the impedance matching circuit A. In a fifth method step, the first transformation device transforms the received information data A from the impedance matching circuit A into information data B of the impedance matching circuit B. In a sixth method step, the communication device transmits the information data B to the plasma process control system.

The impedance matching circuit A can also be referred to as the first impedance matching circuit. The impedance matching circuit B can also be referred to as the second impedance matching circuit.

The control data A can also be referred to as the first control data. The control data B can also be referred to as the second control data.

The information data A can also be referred to as the first information data. The information data B can also be referred to as second information data.

The first and/or second transformation device is preferably a processor, FPGA, microcontroller, or ASIC, which is programmed or configured according to the suitability, embodiment, or the described method steps, and/or on which a program can be loaded that enables it to execute the described method steps or to implement the suitability or embodiment. A transformation device can also comprise a storage device, among other things.

The communication device is preferably a digital data interface. This can be wired or wireless. This can use one or more data communication protocols known to experts.

Embodiments of the present disclosure are described below by way of example with reference to the drawings.

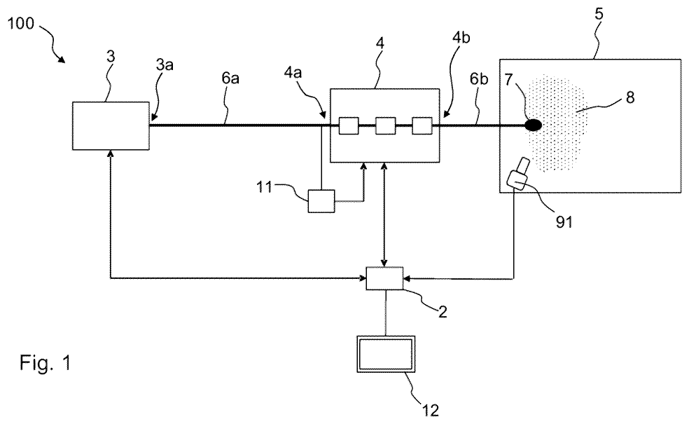

FIG. 1 shows a plasma-generating system 100 which comprises a plasma process control system 2. The plasma-generating system 100 further comprises an RF generator 3, an impedance matching circuit B 4 and at least one consumer 5, in particular in the form of a plasma chamber. The RF generator 3 is designed to supply a radio-frequency signal, in particular in the form of a pulsed radio-frequency signal, with a nominal power P_{Nenn} and a frequency f₀, and to output it at an output terminal 3a. The impedance matching circuit B 4 comprises an input terminal 4a, wherein the RF generator 3 with its output terminal 3a is connected to the input terminal 4a via a first cable connection 6a. The impedance matching circuit B 4 further comprises an output terminal 4b. The output terminal 4b is connected to the at least one consumer 5 via a second cable connection 6b. The first and/or second cable connection 6a, 6b can comprise one or a plurality of cables, for example connected in series and/or in parallel. Coaxial cables are preferably used.

The consumer 5, i.e., the plasma chamber, comprises at least one electrode 7 for generating a plasma 8. The electrode 7 is connected to the output terminal 4b of the impedance matching circuit B 4. In this exemplary embodiment, a camera system 91 is arranged in the plasma chamber, which is designed to monitor the plasma 8.

The plasma process control system 2 is preferably a processor, and/or FPGA and/or microcontroller, and/or ASIC, which is programmed or configured according to the suitability, embodiment, or the described method steps, and/or on which a program can be loaded that enables it to execute the described method steps or to implement the suitability or embodiment. The plasma process control system 2 can also comprise a storage device for this purpose, among other things.

The plasma process control system 2 is designed to control the RF generator 3, in particular to activate or deactivate it. Additionally or alternatively, the plasma process control system 2 is also designed to change the power and/or frequency of the RF signal by appropriately controlling the RF generator 3. Additionally or alternatively, the plasma process control system 2 is also designed to change the waveform of the radio-frequency signal by appropriately controlling the RF generator 3. This could include, for example: type of radio-frequency signal, modulation of the RF signal, pulse durations, pulse repetition rate.

The plasma process control system 2 is likewise preferably designed to control the impedance matching circuit B 4. In particular, the plasma process control system 2 is designed to change the transformation ratio within the impedance matching circuit B 4 and/or to specify an impedance at the output terminal 4b. Additionally or alternatively, the plasma process control system 2 is designed to specify the impedance at the input terminal 4a, which acts on the RF generator 2. For this purpose, the plasma process control system 2 transmits control data B to the impedance matching circuit B 4.

The plasma-generating system 1 also includes a measuring unit 11. The measuring unit 11 is preferably arranged between the RF generator 3 and the impedance matching circuit B 4. The measuring unit 11 is designed, for example, to measure power transmitted from the RF generator 3 towards the impedance matching circuit B 4, and to measure power reflected back towards the RF generator 3. In principle, the measuring unit 11 can also be designed to measure a value for the impedance at the input terminal 4a of the impedance matching circuit 4.

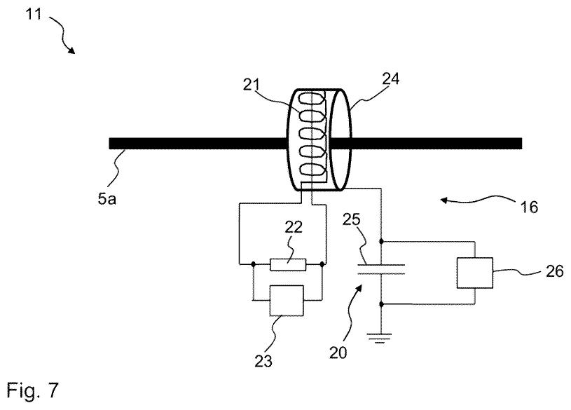

For this purpose, the measuring unit 11 comprises, for example, a directional coupler unit. The measuring unit 11 can measure the power of a forward and reverse radio-frequency signal on the first cable connection 6a via the directional coupler unit in order to calculate the respective power or impedance at the input terminal 4a. The measuring unit 11 can alternatively also comprise a current sensor 16 and a voltage sensor 20. A design with a current sensor 16 and a voltage sensor 20 is shown in FIGS. 7 and 8. The control device 1 is designed to calculate the respective power or impedance at the input terminal 4a, as seen by the RF generator 3, based on the measurement result of the directional coupler unit or the current sensor 16 and the voltage sensor 20.

The plasma-generating system 1 preferably also comprises an operating unit 12. The operating unit 12 is preferably a screen, in particular a touch-sensitive screen. In addition to a screen, the operating unit 12 can also comprise input means such as a keyboard and/or mouse. The operating unit 12 can also be a web server that provides data and receives user input. The plasma process control system 2 is designed to display current settings of the RF generator 3 and/or the impedance matching circuit B 4 on the operating unit 12.

The plasma process control system 2 is preferably designed to receive setpoint specifications, for example for the power of the radio-frequency signal, from the operating unit 12. Furthermore, the frequency of the radio-frequency signal and/or the waveform of the radio-frequency signal and/or the pulse rate and/or the pulse duration for the radio-frequency signal can be received by the operating unit 12. A desired impedance at the output terminal 4b of the impedance matching circuit B 4 can also be received via the operating unit 12. This allows corresponding control variables for RF generator 3 and control data B for impedance matching circuit B 4 to be generated and transmitted to them.

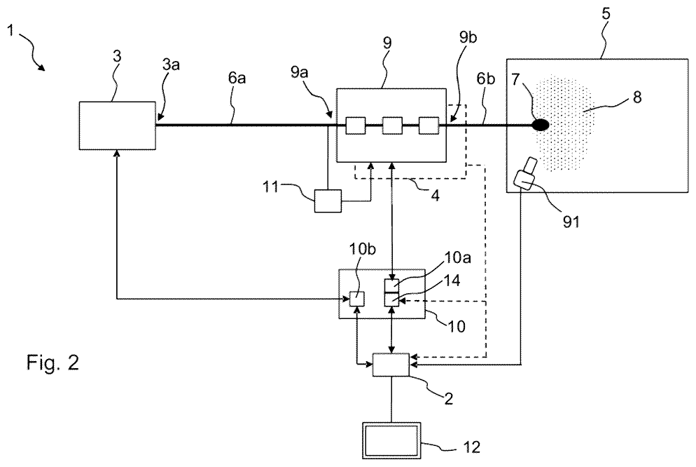

FIGS. 2 and 3 show two variants of a plasma-generating system 1, each modified compared to the plasma-generating system 100 from FIG. 1. In both variants, the impedance matching circuit B 4 is replaced by an impedance matching circuit A 9. The impedance matching circuit A 9 also comprises an input terminal 9a and an output terminal 9b. The impedance matching circuit A 9 is also connected between the RF generator 3 and the consumer 5.

The design of the impedance matching circuit A 9 differs from the design of the impedance matching circuit B 4 at least in that, in the event that the same control data is transmitted to the impedance matching circuit A 9 as to the impedance matching circuit B 4, a different impedance is present at the output terminal 9b of the impedance matching circuit A 9.

One reason for replacing the impedance matching circuit B 4 with the impedance matching circuit A 9 could be, for example, that a larger impedance range is to be provided at the output terminal 9a of the impedance matching circuit A 9, or that the efficiency of the plasma-generating system 1 is to be increased by using the impedance matching circuit A 9. It is also provided that certain components of the impedance matching circuit B 4 are no longer available, so that an impedance matching circuit with modified electrical properties must inevitably be produced.

In order to be able to use such a new impedance matching circuit A 9 without adapting the plasma process control system 2, the present disclosure provides for the use of a transformation system 10 according to the present disclosure.

In FIG. 2, the transformation system 10 according to the present disclosure is arranged between the plasma process control system 2 and the impedance matching circuit A 9, as well as between the plasma process control system 2 and the RF generator 3. The plasma process control system 2 subsequently communicates, in particular only, via the transformation system 10 with the impedance matching circuit A 9 and/or the RF generator 3. Preferably, both the communication from the plasma process control system 2 to the impedance matching circuit A 9 and/or to the RF generator 3 and the communication from the impedance matching circuit A 9 and/or the RF generator 3 to the plasma process control system 2 is routed via the transformation system 10.

The transformation system 10 comprises a communication device 14, via which data transmission with the plasma process control system 2 is made possible. The transformation system 10 also comprises a first transformation device 10a, which is designed to receive control data B for the impedance matching circuit B 4 from the plasma process control system 2 and to transform it into control data A for the impedance matching circuit A 9. The transformation system 10 is designed to control the impedance matching circuit A 9 with the transformed control data A. This control process also comprises transmitting this transformed control data A to the impedance matching circuit A 9.

The first transformation device 10a preferably comprises a transformation table and/or a transformation function to transform the control data B, intended for controlling the impedance matching circuit B 4, into control data A for the impedance matching circuit A 9.

The impedance matching circuit B 4 is not physically present in either the exemplary embodiment shown in FIG. 2 or in the exemplary embodiment shown in FIG. 3. For the plasma process control system 2, however, it behaves as if it were present. Therefore, in both FIGS. 2 and 3, the impedance matching circuit B 4 is shown as a dashed line in the background.

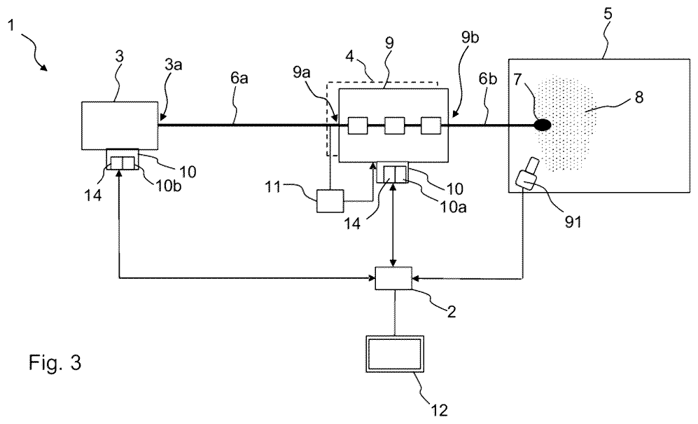

The control data B for the impedance matching circuit B 4 comprises control variables for at least one mechanically, in particular motor-driven, adjustable reactance in the impedance matching circuit B 4. The control data A for the impedance matching circuit A 9 comprises control variables for at least one mechanically, in particular motor-driven, adjustable reactance 52, 53, as shown in FIGS. 4A, 4B, for the impedance matching circuit A 9.

The transformation system 10 is preferably designed to receive information data A from the impedance matching circuit A 9. The first transformation device 10a is designed to transform the received information data A from the impedance matching circuit A 9 into information data B of the impedance matching circuit B 4. The communication device 14 is designed to transmit the transformed information data B to the plasma process control system 2. Consequently, the plasma process control system 2 receives information data B that plausibly correspond to the information data that would have been output by impedance matching circuit B 4. This is particularly advantageous when the information data B is displayed on the operating unit 12.

The information data A is in particular current position information for at least one mechanically, in particular motor-driven, adjustable reactance 52, 53 in the impedance matching circuit A 9 and/or current capacitance information for at least one mechanically, in particular motor-driven, adjustable reactance 52, 53 in the impedance matching circuit A 9 and/or a currently set transformation ratio in the impedance matching circuit A 9 and/or a current efficiency of the impedance matching circuit A 9 and/or at least a current value for a voltage and/or current at or in the impedance matching circuit A 9.

The first transformation device 10a preferably comprises a transformation table and/or a transformation function to transform the information data A for the impedance matching circuit A 9 into information data B for the impedance matching circuit B 4.

The communication device 14 of the transformation system 10 is preferably also designed to receive a target generator power for the RF generator 3 for use of the impedance matching circuit B 4 from the plasma process control system 2. The transformation system 10 comprises a second transformation device 10b. The second transformation device 10b is designed to transform the target generator power for use by the impedance matching circuit B 4 into a target generator power for use by the impedance matching circuit A 9. The second transformation device 10b is designed to transmit the modified target generator power to the RF generator 3.

The second transformation device 10b is designed to reduce the target generator power received by the plasma process control system 2 when the efficiency of the impedance matching circuit A 9 is greater than the efficiency of the impedance matching circuit B 4. Additionally or alternatively, the second transformation device 10b is designed to increase the target generator power received by the plasma process control system 2 when the efficiency of the impedance matching circuit A 9 is less than the efficiency of the impedance matching circuit B 4.

Preferably, the second transformation device 10b is designed to receive an actual generator power from the RF generator 3 with connected impedance matching circuit A 9. The second transformation device 10b is designed to increase the actual generator power when the efficiency of the impedance matching circuit A 9 is greater than the efficiency of the impedance matching circuit B 4. The communication device 14 is designed to transmit the increased actual generator power to the plasma process control system 2. Additionally or alternatively, the second transformation device 10b is designed to reduce the actual generator power when the efficiency of the impedance matching circuit A 9 is less than the efficiency of the impedance matching circuit B 4. The communication device 14 is designed to transmit the reduced actual generator power to the plasma process control system 2.

The communication device is 14 designed to receive a frequency setpoint for the RF generator 3 from the plasma process control system 2. The second transformation device 10b is designed to transmit the frequency setpoint to the RF generator 3 without changing the frequency. Additionally or alternatively, the second transformation device 10b is designed to receive an actual frequency value from the RF generator 3 and to transmit the actual frequency value to the plasma process control system 2 without changing the frequency by means of the communication device 14.

In FIG. 2, the transformation system 10 is designed as a separate system between the RF generator 3, the impedance matching circuit A 9 and the plasma process control system 2.

In contrast to FIG. 2, the transformation system 10 in FIG. 3 is designed both in the RF generator 3 and in the impedance matching circuit A 9. In this case, the first transformation device 10a is arranged in the impedance matching circuit A 9 and the second transformation device 10b is in the RF generator 3. The corresponding communication device 14 of the transformation system 10 is arranged both in the impedance matching circuit A 9 and in the RF generator 3. The plasma process control system 2 then communicates directly with the first or second transformation device 10a, 10b in the impedance matching circuit A 9 or in the RF generator 3.

The following applies to both the exemplary embodiment according to FIG. 2 and the exemplary embodiment according to FIG. 3:
The transformation system 10 can, without restrictions, be at least partially arranged or implemented on or in the plasma process control system 2.
The transformation system 10 can, without restrictions, be at least partially arranged or implemented on or in the RF generator 3.
The transformation system 10 can, without restrictions, be arranged or implemented at least partially on or in the impedance matching circuit A 9, in particular within a control unit of the impedance matching circuit A 9.

FIGS. 4A and 4B show exemplary embodiments of the impedance matching circuit A 9. In principle, the impedance matching circuit B 4 can also be constructed in an analogous manner, wherein the positions for the mechanically, in particular motor-driven, adjustable reactances 52, 53 are different in order to achieve the same capacitance values.

If the impedance matching circuit A 9 contains a plurality of impedance transformation stages, each impedance transformation stage can be constructed according to the exemplary embodiment shown in FIGS. 4A, 4B. It is understood that the impedance matching circuit A 9 can also be designed differently than shown in FIGS. 4A, 4B.

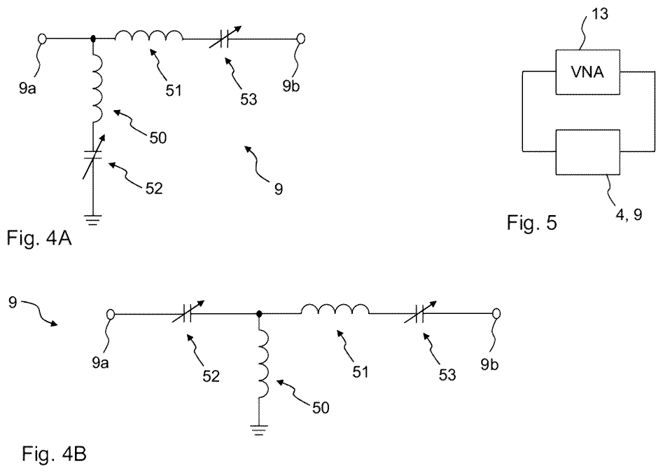

The input terminal 9a of the impedance matching circuit A 9 is connected in FIG. 5A to a first coil 50 or first inductance and to a second coil 51 or second inductance. The first and second coils 50, 51 are connected with their first terminal to a common node and thus to the input terminal 9a of the impedance matching circuit A 9. The first coil 50 is connected to a reference ground via a first capacitor 52 or first capacitance. The second coil 51 is connected to the output terminal 9b via a second capacitor 53 or second capacitance. The first and/or second capacitors 52, 53 are adjustable components, in particular in the form of rotary capacitors, the capacitance of which can be changed via stepper motors. In particular, the plate spacing of the first and second capacitors 52, 53 can be changed. The plasma process control system 2 is designed to control the respective stepper motors accordingly. The capacitances of the first and second capacitors 52, 53 can be adjusted independently of each other. Preferably, the impedance matching circuit A 9 is free of additional components. Of course, the position of the first coil 50 and the first capacitor 52 can also be exchanged. In this case, the first capacitor 52 is arranged at the input terminal 9a of the impedance matching circuit A 9 and the first coil 50 is arranged at the reference ground. Additionally or alternatively, the position of the second coil 51 and the second capacitor 53 can also be exchanged. In this case, the second capacitor 53 is arranged at the input terminal 9a of the impedance matching circuit A 9 and the second coil 51 is arranged at the output terminal 9b of the impedance matching circuit A 9.

The input terminal 9a of the impedance matching circuit A 9 is connected to the first capacitor 52 or first capacitance in FIG. 4B. The first capacitor 52 is connected to both the first coil 50 or first inductance and the second coil 51 or second inductance. This is done via a common node, to which both the first capacitor 52 and the first and second coils 50, 51 are connected. The first coil 50 is still connected to the reference ground. The second coil 51 is connected to the second capacitor 53 or second capacitance, in particular in series. The second capacitor 53 is connected to the output terminal 9b of the impedance matching circuit A 9. The position of the second coil 51 and the second capacitor 53 could also be reversed. In this case, the second capacitor 53 would be connected to the common node and the second coil 51 would be connected to the output terminal 9b of the impedance matching circuit A 9. Preferably, the impedance matching circuit A 9 is free of additional components.

FIG. 5 shows an exemplary embodiment which explains how a transformation table and/or a transformation function for the transformation system 10 can be generated. A vector network analyzer 13 is connected to the input terminal 4a and the output terminal 4b of the impedance matching circuit B 4. Then an impedance at the output terminal 4b is determined for a position for at least one mechanically, in particular motor-driven, adjustable reactance of the impedance matching circuit B 4. Subsequently, the position of at least one mechanically, in particular motor-driven, adjustable reactance of the impedance matching circuit B 4 is changed. Subsequently, the impedance and the adjustment of the reactance are determined again. The vector network analyzer 13 is then connected to the input terminal 9a and the output terminal 9b of the impedance matching circuit A 9. The impedance at output terminal 9b is determined for a position for at least one mechanically, in particular motor-driven, adjustable reactance 52, 53 of the impedance matching circuit A 9. Subsequently, the position of at least one mechanically, in particular motor-driven, adjustable reactance 52, 53 of the impedance matching circuit A 9 is changed. Subsequently, the impedance is determined and the reactance 52, 53 is adjusted again. Based on this information, a transformation table and/or a transformation function can be created by which a position of the at least one mechanically, in particular motor-driven, adjustable reactance of the impedance matching circuit B 4 can be transformed into a position for the at least one mechanically, in particular motor-driven, adjustable reactance 52, 53 of the impedance matching circuit A 9, wherein the impedance at the output terminal 9b of the impedance matching circuit A 9 is equal to the impedance at the output terminal 4b of the impedance matching circuit B 4 or deviates by less than a threshold value.

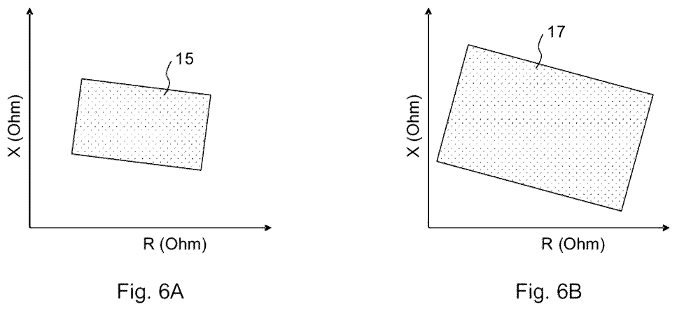

FIGS. 6A and 6B show differently adjustable impedances 15, 17 at output terminal 4b, 9b at the impedance matching circuit B 4 (FIG. 6A) and the impedance matching circuit A 9 (FIG. 6B). The impedances 15, 17 can have complex values, i.e., with a real part R (Ohm) and an imaginary part X (Ohm). Therefore, the possible impedances 15, 17 are each represented as surfaces. It can be seen that the newer impedance matching circuit A 9 can set a larger area of impedances 17 at its output terminal 9b than the older impedance matching circuit B 4. For each of the possible adjustable impedance values there is a position for at least one mechanically, in particular motor-driven, adjustable reactance 52, 53. In particular, motor positions for setting a first impedance at output terminal 4b of the impedance matching circuit B 4 are different from motor positions for setting the same first impedance at output terminal 9b of the impedance matching circuit A 9.

Instead of mechanically, especially motor-driven, variable reactances, electrically and/or magnetically variable reactances can also be provided.

FIGS. 7 and 8 each show an exemplary embodiment of a design of the measuring unit 11. The measuring unit 11 is designed to measure voltage and current without contact.

For this purpose, the measuring unit 11 comprises a current sensor 16 and a voltage sensor 20.

The measuring unit 11 can be arranged between RF generator 3 and impedance matching circuit A 9, whereby the cable 5a shown in FIG. 7 or FIG. 8 can be implemented through the second cable connection 6a from one of FIG. 2 or 3.

The measuring unit 11 can be arranged at the input of the impedance matching circuit A 9.

The measuring unit 11 can be arranged at the output of the RF generator 3.

However, it is still preferable to measure the phase relationship between current and voltage so that the impedance can be calculated, for example.

The current sensor 16 of the measuring unit 11 is a coil 21, in particular in the form of a Rogowski coil. Both ends of the coil are preferably connected to each other via a shunt resistor 22. The voltage, which drops across the shunt resistor 22, can be digitized by means of a first A/D converter 23.

The voltage sensor 20 of the measuring unit 11 is preferably built as a capacitive voltage divider. A first capacitor 24 is formed by an electrically conductive ring 24. An electrically conductive cylinder could also be used. The corresponding first cable connection 6a is guided through this electrically conductive ring 24. A second capacitor 25 of the voltage sensor 20, which is constructed as a voltage divider, is connected to the reference ground. A second A/D converter 26 is connected in parallel to the second capacitor 25 and is designed to detect and digitize the voltage which drops across the second capacitor 25.

In principle, the measuring unit 11 can also be arranged or built on an, in particular common, circuit board. The first capacitor 24 can be formed by a coating on a first and an opposite second side of the circuit board. In this case, the coatings on the first side and the second side are electrically connected to each other by vias. The first cable connection 5a is guided through an opening in the circuit board. The second capacitor 25 can be formed by a discrete component.

The current sensor 16 in the form of the coil 21, in particular in the form of the Rogowski coil, is further spaced apart from the first cable connection 5a than the first capacitor 24. The coil can also be formed on the same circuit board by corresponding coatings and vias. The coil for current measurement and the first capacitor for voltage measurement preferably run through a common plane.

The shunt resistor 22 can also be arranged on this circuit board. The same applies to the first and/or second A/D converter 23, 23.

The measuring unit 11 can also be designed as a directional coupler unit.

In principle, the measuring unit 11 can also be arranged between the impedance matching circuit 3 and the load 5 in the form of the plasma chamber. In this case, the second cable connection 6b can be employed for current and voltage measurement, whereby the cable 5a shown in FIG. 7 or FIG. 8 is implemented through the second cable connection 6b from one of FIG. 1, 2, or 3. The input impedance can then be calculated by taking into account a known transformation ratio of the impedance matching circuit 3.

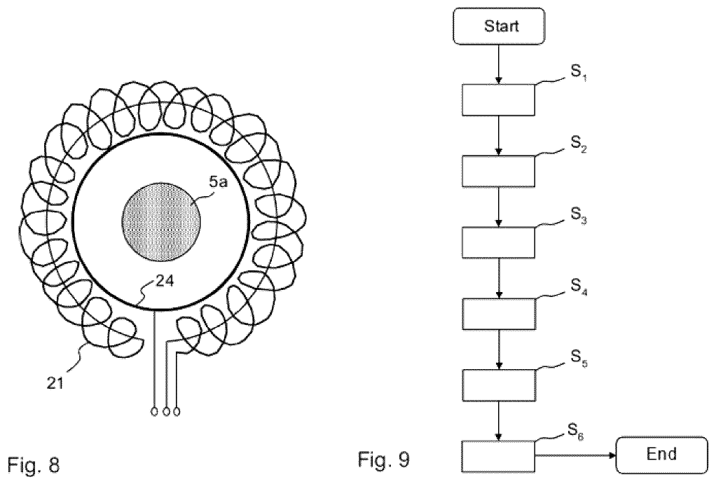

FIG. 9 shows a flowchart for a method which explains the operation of the transformation system 10.

The plasma process control system 2 is connected to the impedance matching circuit A 9 via the transformation system 10. In a first method step S₁, a communication device 14 of the transformation system 10 receives control data B for an impedance matching circuit B 4 from the plasma process control system 2. In a second method step S₂, the first transformation device 10a transforms the control data B for the impedance matching circuit B 4 into control data A for the impedance matching circuit A 9. In a third method step S₃, the transformation system 10 provides the transformed control data A of the impedance matching circuit A 9. Additionally or alternatively to method steps S₁, S₂, S₃, the following method steps S₄, S₅, S₆ can also be carried out. In a fourth method step S₄, the transformation system 10 receives information data A from the impedance matching circuit A 9. In a fifth method step S₅, the first transformation device 10a transforms the received information data A from the impedance matching circuit A 9 into information data B of the impedance matching circuit B 4. In a sixth method step S₆, the communication device 14 transmits the information data B to the plasma process control system 2.

The present disclosure is not limited to the described exemplary embodiments. Within the scope of the present disclosure, all described and/or drawn features can be combined with one another.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A transformation system for connecting a plasma process control system to an impedance matching circuit A, wherein the impedance matching circuit A is connectable to an RF generator and a plasma chamber, the transformation system comprising:
a first transformation device and a communication device, wherein the communication device is connectable to the plasma process control system;
wherein:
a)—the communication device is designed to receive from the plasma process control system control data B for an impedance matching circuit B;
the first transformation device is designed to transform the control data B for the impedance matching circuit B into control data A for the impedance matching circuit A; and
the transformation system is designed to provide the control data A for controlling the impedance matching circuit A;
and/or
b)—the transformation system is designed to receive information data A from the impedance matching circuit A;
the first transformation device is designed to transform the received information data A from the impedance matching circuit A into information data B of the impedance matching circuit B; and
the communication device is designed to transmit the information data B to the plasma process control system.

2. The transformation system according to claim 1, wherein:
the transformation system is designed to transmit the control data A to the impedance matching circuit A and to thereby control the impedance matching circuit A.

3. The transformation system according to claim 1, wherein:
the first transformation device comprises a transformation table and/or a transformation function to transform the control data B for the impedance matching circuit B into control data A for the impedance matching circuit A.

4. The transformation system according to claim 1, wherein:
the control data B for the impedance matching circuit B comprises control variables for at least one mechanically motor-driven adjustable reactance in the impedance matching circuit B, and
the control data A for the impedance matching circuit A comprises control variables for at least one mechanically, in particular motor-driven, adjustable reactance for the impedance matching circuit A.

5. The transformation system according to claim 1, wherein:
the control data B for the impedance matching circuit B comprises:
a) position information; and/or
b) capacity information;
for at least one mechanically motor-driven adjustable reactance arranged in the impedance matching circuit B to provide a specific target impedance value at the output terminal of the impedance matching circuit B, and
the first transformation device is designed to transform the control data B for the impedance matching circuit B into control data A for the impedance matching circuit A, wherein the control data A for the impedance matching circuit A comprises position information for at least one mechanically motor-driven adjustable reactance arranged in the impedance matching circuit A, by which the same target impedance value can be provided at the output terminal of the impedance matching circuit A as at the output terminal of the impedance matching circuit B.

6. The transformation system according to claim 1, wherein:
the information data A comprises at least one of the following values:
a) a current position information for at least one mechanically motor-driven adjustable reactance in the impedance matching circuit A,
b) current capacity information for at least one mechanically motor-driven adjustable reactance in the impedance matching circuit A,
c) a currently set transformation ratio in the impedance matching circuit A,
d) a current efficiency of the impedance matching circuit A, and/or
e) at least one current value for a voltage and/or current at or in the impedance matching circuit A.

7. The transformation system according to claim 1, wherein:
the first transformation device comprises a transformation table and/or a transformation function to transform the information data A for the impedance matching circuit A into information data B for the impedance matching circuit B.

8. The transformation system according to claim 1, wherein:
the communication device is designed to receive a target generator power B for the RF generator for use of the impedance matching circuit B from the plasma process control system;
a second transformation device is provided, wherein the second transformation device is designed to transform the target generator power B for use by the impedance matching circuit B into a target generator power A for use by the impedance matching circuit A;
the second transformation device is designed to transmit the target generator power A to the RF generator (3).

9. The transformation system according to claim 8, wherein:
the second transformation device is designed to transform the target generator power B received by the plasma process control system as a function of a quantity, wherein the quantity can describe an efficiency difference between the impedance matching circuit A and the impedance matching circuit B.

10. The transformation system according to claim 8, wherein:
the second transformation device is designed to transform the target generator power B received by the plasma process control system as a function of an efficiency difference between an efficiency of the impedance matching circuit A and an efficiency of the impedance matching circuit B, wherein the efficiency of the impedance matching circuit A is obtained when operating with the control variable A and wherein the efficiency of the impedance matching circuit B is obtained when operating with the control variable B.

11. The transformation system according to claim 8, wherein:
the second transformation device is designed to reduce the target generator power B received by the plasma process control system when the efficiency of the impedance matching circuit A is greater than the efficiency of the impedance matching circuit B.

12. The transformation system according to claim 8, wherein:
the second transformation device is designed to receive an actual generator power from the RF generator with connected impedance matching circuit A,
wherein:
a) the second transformation device is designed to increase the actual generator power when the efficiency of the impedance matching circuit A is greater than the efficiency of the impedance matching circuit B,
the communication device is designed to transmit the increased actual generator power to the plasma process control system,
and/or
b) the second transformation device is designed to reduce the actual generator power when the efficiency of the impedance matching circuit A is less than the efficiency of the impedance matching circuit B, and
the communication device is designed to transmit the reduced actual generator power to the plasma process control system.

13. The transformation system according to claim 1, wherein:
the communication device is designed to receive a frequency setpoint for the RF generator from the higher-level plasma process control system, and
the second transformation device is designed to transmit the frequency setpoint to the RF generator without changing the frequency.

14. A plasma-generating system having the transformation system according to claim 1, an RF generator, an impedance matching circuit A, and a plasma process control system, wherein:
the plasma process control system is connected to the transformation system;
the RF generator is connected to the impedance matching circuit A;
the plasma process control system is connected to the transformation system.

15. The plasma-generating system according to claim 14, wherein:
the transformation system is:
a) designed as a separate system between the RF generator, the impedance matching circuit A, and the plasma process control system, or
b) designed as a module in the RF generator and in the impedance matching circuit A, or
c) designed as a module in the plasma process control system.

16. A method for generating a transformation table and/or a transformation function to transform control data B for the impedance matching circuit B into control data A for the impedance matching circuit A, wherein the method comprises:
connecting a vector network analyzer to an input terminal and an output terminal of the impedance matching circuit B;
determining an impedance at the output terminal for a position for at least one mechanically motor-driven adjustable reactance of the impedance matching circuit B;
changing the position of the at least one mechanically motor-operated adjustable reactance of the impedance matching circuit B and repeating the determining method step;
connecting the vector network analyzer to the input terminal and the output terminal of the impedance matching circuit A;
determining an impedance at the output terminal for a position for at least one mechanically motor-driven adjustable reactance of the impedance matching circuit A;
changing the position of the at least one mechanically motor-operated, adjustable reactance of the impedance matching circuit A and repeating the determining method step;
creating a transformation table and/or a transformation function, by which the position of the at least one mechanically motor-driven adjustable reactance of the impedance matching circuit B can be transferred into the position for the at least one mechanically motor-driven adjustable reactance of the impedance matching circuit A, wherein the impedance at the output terminal of the impedance matching circuit A:
a) is equal to the impedance at the output terminal of the impedance matching circuit B, or
b) deviates by less than a threshold value.
